(19) United States
(12) Patent Application Publication
(10) Pub. No.: US 2026/0117379 A1
(43) Pub. Date: Apr. 30, 2026

(54) SHOWERHEAD ASSEMBLY FOR DISTRIBUTING A GAS WITHIN A REACTION CHAMBER AND A METHOD FOR CONTROLLING THE TEMPERATURE UNIFORMITY OF A SHOWERHEAD ASSEMBLY

(71) Applicant: ASM IP Holding B.V., Almere (NL)

(72) Inventors: Melvin Verbaas, Gilbert, AZ (US); Jereld Lee Winkler, Gilbert, AZ (US); John Kevin Shugrue, Phoenix, AZ (US); Carl Louis White, Gilbert, AZ (US)

(21) Appl. No.: 19/078,682

(22) Filed: Mar. 13, 2025

Related U.S. Application Data
(63) Continuation of application No. 16/042,791, filed on Jul. 23, 2018, now Pat. No. 12,276,023.
(60) Provisional application No. 62/541,580, filed on Aug. 4, 2017.

(51) Int. Cl. C23C 16/455

(52) U.S. Cl. CPC C23C 16/45565; C23C 16/4557; C23C 16/45572

(57) ABSTRACT

A showerhead assembly for distributing a gas within a reaction chamber is disclosed. The showerhead assembly may comprise: a chamber formed within the showerhead assembly and a gas distribution assembly adjacent to the chamber, wherein the gas distribution assembly comprises: a first gas distribution plate comprising a top surface and a bottom surface; and a second gas distribution plate comprising a top surface and a bottom surface, the second gas distribution plate being disposed over the top surface of the first gas distribution plate. The gas distribution assembly may further comprise: one or more heating structures disposed between the first gas distribution plate and the second gas distribution plate; and a plurality of apertures extending from the bottom surface of the first distribution plate to the top surface of the second gas distribution plate. Methods for controlling the temperature uniformity of a showerhead assembly utilized for distribution gas with a reaction chamber are also disclosed.

### CROSS-REFERENCE TO RELATED APPLICATIONS

This application is a continuation of, and claims priority to and the benefit of, U.S. patent application Ser. No. 16/042,791, filed Jul. 23, 2018 and entitled “SHOWERHEAD ASSEMBLY FOR DISTRIBUTING A GAS WITHIN A REACTION CHAMBER,” which is a nonprovisional of, and claims priority to and the benefit of, U.S. Provisional Patent Application No. 62/541,580, filed on Aug. 4, 2017 and entitled “SHOWERHEAD ASSEMBLY FOR DISTRIBUTING A GAS WITHIN A REACTION CHAMBER AND A METHOD FOR CONTROLLING THE TEMPERATURE UNIFORMITY OF A SHOWERHEAD ASSEMBLY,” both of which are hereby incorporated by reference herein.

### FIELD OF INVENTION

The present disclosure generally relates to a showerhead assembly for distributing a gas within a reaction chamber and a method for controlling the temperature uniformity of a showerhead assembly utilized for distributing a gas within a reaction chamber.

### BACKGROUND OF THE DISCLOSURE

Gas-phase reactors, such as chemical vapor deposition (CVD), plasma-enhanced CVD (PECVD), atomic layer deposition (ALD), and the like can be used for a variety of applications, including depositing and etching materials on a substrate surface. For example, gas-phase reactors can be used to deposit and/or etch layers on a substrate to form semiconductor devices, flat panel display devices, photovoltaic devices, microelectromechanical systems (MEMS), and the like.

A typical gas-phase reactor system includes a reactor including a reaction chamber, one or more precursor gas sources fluidly coupled to the reaction chamber, one or more carrier or purge gas sources fluidly coupled to the reaction chamber, a gas distribution system to deliver gases (e.g., precursor gas(es) and/or carrier or purge gas(es)) to a surface of a substrate, and an exhaust source fluidly coupled to the reaction chamber. The system also typically includes a susceptor to support a substrate in place during processing. The susceptor can be configured to move up and down to receive a substrate and/or can rotate during substrate processing.

The gas distribution system may include a showerhead assembly for distributing gas(es) to a surface of the substrate. The showerhead assembly is typically located above the substrate. During substrate processing, gas(es) flow from the showerhead assembly in a downward direction towards the substrate and then outward over the substrate. An example showerhead assembly may include a gas distribution assembly with a chamber adjacent to one surface of the distribution assembly and a plurality of apertures spanning between the chamber and a distribution surface (substrate side) of the distribution assembly.

The temperature and particularly the temperature uniformity across the surface of the gas distribution assembly facing the substrate is an important parameter to control in gas-phase reactors. For example, in gas-phase reactors configured for performing deposition processes, a substantial thermal differential across the surface of the gas distribution assembly facing the substrate may result in transitional deposition across the exposed surface of the gas distribution assembly which may further result in an increase in undesired particles and a subsequent increase in the need for tool maintenance. Accordingly, a showerhead assembly with improved temperature uniformity and methods for controlling the temperature uniformity of a showerhead assembly are desired.

### SUMMARY OF THE DISCLOSURE

In accordance with at least one embodiment of the disclosure, a showerhead assembly for distributing a gas within a reaction chamber is disclosed. The showerhead assembly may comprise: a chamber formed within the showerhead assembly and a gas distribution assembly adjacent to the chamber. The gas distribution assembly may comprise: a first gas distribution plate comprising a top surface and a bottom surface, a second gas distribution plate comprising a top surface and a bottom surface, the second gas distribution plate being disposed over the top surface of the first gas distribution plate. The gas distribution assembly may further comprise: one or more heating structures disposed between the first gas distribution plate and the second gas distribution plate and a plurality of apertures extending from the top surface of the second distribution plate to the bottom surface of the first gas distribution plate.

The current disclosure may also comprise a method for controlling the temperature uniformity of a showerhead assembly utilized for distributing a gas within a reaction chamber. The methods of the disclosure may comprise: providing a first gas distribution plate comprising a top surface and a bottom surface, printing one or more heating structures over the top surface of the first gas distribution plate, and providing a second gas distribution plate comprising a top surface and a bottom surface. Methods of the disclosure may further comprise; coupling the first gas distribution plate to the second gas distribution plate such that the one or more heating structures are disposed between the top surface of the first gas distribution plate and the bottom surface of the second gas distribution plate, and forming a plurality of apertures extending from the top surface of the second gas distribution plate to the bottom surface of the first gas distribution plate.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawing, in which:

FIG. 1 illustrates a showerhead assembly in accordance with exemplary embodiments of the disclosure;

FIGS. 2A, 2B and 2C illustrates a showerhead assembly in accordance with exemplary embodiments of the disclosure;

FIG. 3 illustrates an expanded cross section view of a portion of a gas distribution assembly in accordance with exemplary embodiments of the disclosure;

FIG. 4 illustrates an expanded cross section view of a portion of a gas distribution assembly in accordance with exemplary embodiments of the disclosure;

FIG. 5 illustrate an expanded cross section view of a portion of a gas distribution assembly in accordance with exemplary embodiments of the disclosure;

FIG. 6 illustrates an expanded cross section view of a portion of a gas distribution assembly in accordance with exemplary embodiments of the disclosure;

FIGS. 7A, 7B, 7C, 7D, 7E, 7F, 7G and 7H illustrate methods for fabricating a gas distribution assembly in accordance with exemplary embodiments of the disclosure;

FIGS. 8A, 8B, 8C, 8D, 8E and 8F illustrate methods for fabricating a gas distribution assembly in accordance with exemplary embodiments of the disclosure;

FIGS. 9A, 9B and 9C illustrate methods for fabricating a gas distribution assembly in accordance with exemplary embodiments of the disclosure;

FIGS. 10A, 10B and 10C illustrate methods for fabricating a gas distribution assembly in accordance with exemplary embodiments of the disclosure;

FIGS. 11A and 11B illustrates exemplary heating configurations in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those skilled in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The embodiments of the disclosure may include a showerhead assembly for distributing a gas within a reaction chamber and may further include a method for controlling the temperature uniformity of a showerhead assembly utilized for distributing a gas within a reaction chamber. The embodiments of the disclosure may particularly include a showerhead assembly including a gas distribution assembly wherein the temperature uniformity of the gas distribution assembly, and particular the exposed surface of the gas distribution assembly facing the substrate, may be controlled. For example, the gas distribution assembly may comprise two or more gas distribution plates wherein integrated resistive heaters and cooling channels are utilized to control the thermal uniformity of the showerhead assembly and particularly, the thermal uniformity of the exposed surface of the gas distribution assembly facing the substrate.

Common heating technologies for gas-phase reactors and particular for showerhead assemblies may comprise the utilization of one or more coil/cable type heaters disposed in intimate contact with the region to be heated, for example, the coil/cable type heater may comprise a magnesium oxide resistive heating element. The coil/cable type heaters may have limited bending radii which may increase the overall footprint of the heater and limit the power output achievable from the coil/cable type heater. The embodiments of the disclosure propose utilizing one or more heating structures embedded directly within the gas distribution assembly wherein the one or more heating structures may comprise a resistive heating element formed by a printing process.

In some embodiments of the disclosure, the one or more heating structures may comprise a polyimide substrate disposed upon one of the gas distribution panels, the polyimide substrate having a printed heating structure disposed thereon, for example, the printed heating structure may be formed utilizing conductive ink or a screen printing process.

In some embodiments of the disclosure, the one or more heating structures may comprise a dielectric/resistive element/dielectric heating stack disposed upon at least one of the gas distribution plates, wherein the heating stack may be formed entirely by an additive manufacturing process, more commonly referred to as a three-dimensional (3D) printing process. Additive manufacturing or 3D printing technologies create physical objects from 3D data, typically by providing, curing, or fusing material in a layer-by-layer manner. Additive manufacturing technologies include, but are not limited to, extrusions based 3D printing, stereolithography, selective laser sintering (SLS), multi-jet modelling, binder-on-powder 3D printing, laminated object manufacturing, and other technologies.

The embodiments of the disclosure therefore allow the direct printing of one or more heating structures onto one or more of the gas distribution plates comprising the gas distribution assembly. The printing of the one or more heating structures on to at least one of the gas distributions plates allows for a number of improvements over coil/cable type heaters including, but not limited to, more complex heating geometries, multiple independently controlled temperature zones, reduced contamination, and higher power densities.

The embodiments of the disclosure may not only provide a gas distribution assembly within one or more embedded heating structures, but also provide a gas distribution assembly with embedded means for cooling the gas distribution assembly. The ability to both heat and cool the showerhead assembly adds a further degree of control over the temperature uniformity of the showerhead assembly and particular over the temperature uniformity of the gas distribution assembly.

Current methods for providing cooling to a showerhead assembly may comprise providing a cooling channel disposed around the periphery of the showerhead assembly. The problem with periphery cooling of the showerhead assembly is that it may result in a temperature differential across the gas distribution assembly. For example, the showerhead assembly may be subjected to a high thermal load at the center due to the proximity of the high temperature substrate and may be subjected at the edge of the showerhead assembly to a cooling mechanism. For example, the temperature differential across the surface of the gas distribution assembly facing the high temperature substrate may be as much as high as 40° C.

Therefore, embodiments of the disclosure may provide an improved showerhead assembly, which may comprise a gas distribution assembly comprising at least three (3) gas distribution plates, wherein one or more trenches may be provided in at least one of the gas distribution plates, such that when the at least three (3) gas distribution plates are sealed together at least one sealed cooling channel is created and configured for providing a cooling fluid throughout the gas distribution assembly.

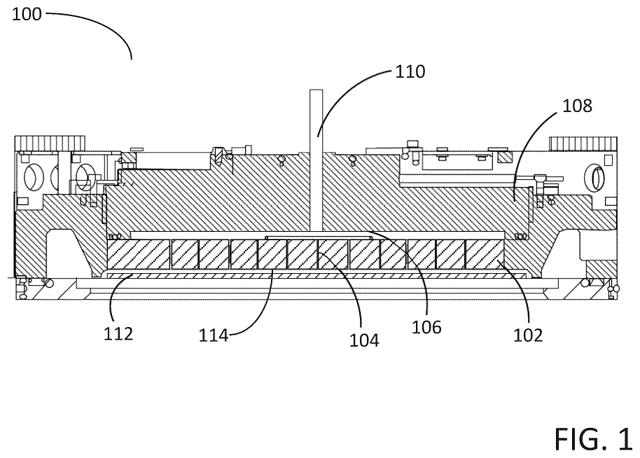

FIG. 1 illustrates an exemplary showerhead assembly 100 in accordance with a non-limiting example embodiment of the disclosure. Showerhead assembly 100 comprises a gas distribution assembly 102, including a plurality of apertures 104, and a chamber or region 106. Showerhead assembly 100 may also include a top plate 108 and a gas inlet 110. It should be noted that the gas distribution assembly 102 illustrated in FIG. 1 is shown in a simplified block form and does not illustrate the detailed embodiments of the disclosure to be described herein.

During operation, one or more purge gases and/or one or more precursors and/or reactants flow through gas inlet 110, to chamber 106, and through apertures 104 toward a substrate 112. In the illustrated example, the direction of the flow of the gas in gas inlet 110 and apertures 104 is substantially vertical, i.e., substantially (e.g., with five (5) degrees of being) perpendicular to a surface of substrate 112. This allows relatively uniform distribution of the gases across a surface of the substrate.

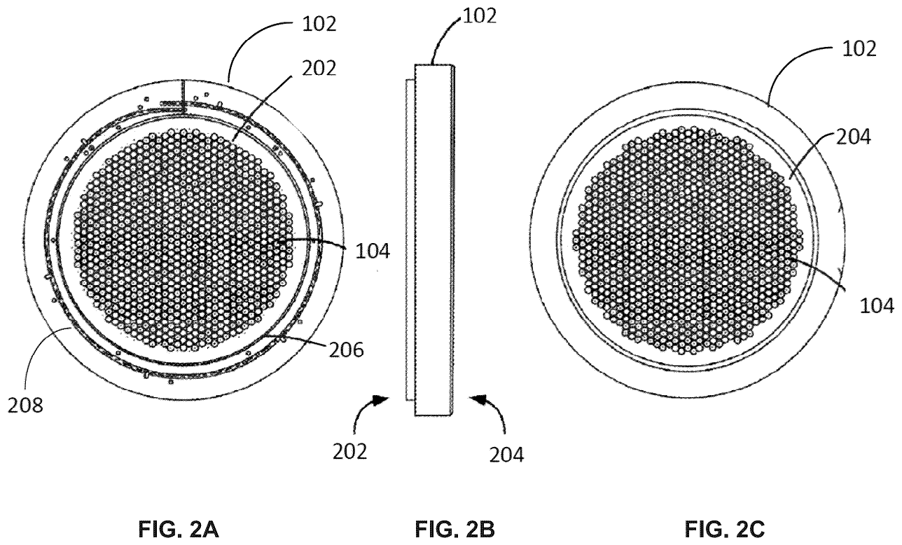

Gas distribution assembly 102 is shown in more detail in FIGS. 2A-2C, wherein FIG. 2A illustrates a top view or chamber view or chamber-side view of gas distribution assembly 102, FIG. 2B illustrates a simplified side view of gas distribution plate 102 and FIG. 2C illustrates a bottom or deposition-side or substrate-side surface view of gas distribution assembly 102.

Gas distribution assembly 102 includes a first (chamber-side) surface 202, a second (substrate-side) surface 204, and a plurality of apertures 104, spanning between the first surface 202 and the second surface 204. Exemplary gas distribution assembly also includes a recess 206 to receive a sealing member, such as a gasket (e.g., elastomeric O-ring) to facilitate forming a seal between the gas distribution assembly 102 and a second plate 108, to thereby form chamber 206 adjacent to the first surface 202. In addition, in some embodiments the gas distribution assembly may comprise heater cable recess 208, in which one or more conventional cable/coil type heaters may be disposed.

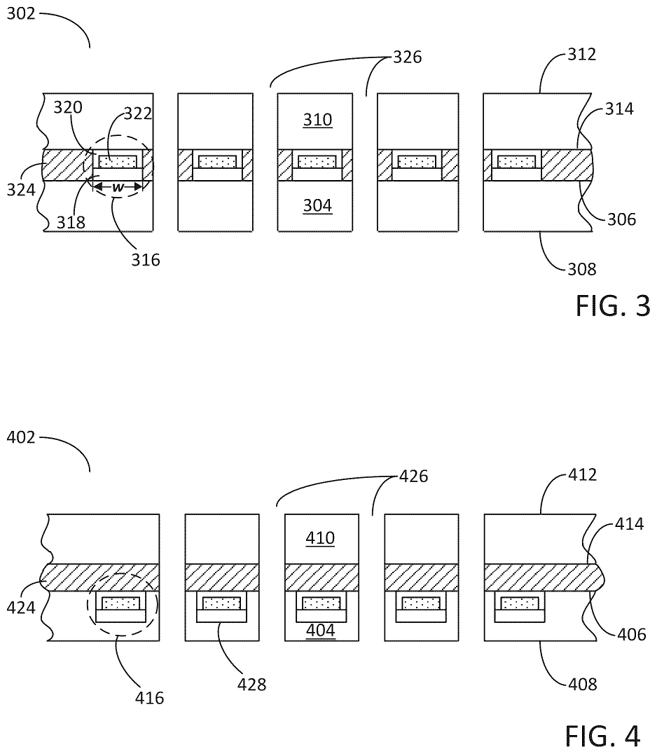

FIG. 3 illustrates an expanded cross section view of a portion of an exemplary gas distribution assembly according to the embodiments of the current disclosure. As a non-limiting example embodiment, FIG. 3 illustrates a gas distribution assembly 302 comprising, a first gas distribution plate 304 comprising a top surface 306 and a bottom surface 308, and a second gas distribution plate 310 comprising a top surface 312 and a bottom surface 314. In some embodiments, the first gas distribution plate 304 and second gas distribution plate 310 may be substantially the same and may be fabricated from materials, including but not limited to, aluminum, titanium, nickel, nickel alloys, ceramics, stainless steel, and Hastelloy.

In some embodiments both the first gas distribution plate 304 and the second gas distribution plate 310 may comprise a circular disc configuration, although other configuration may be utilized. As a non-limiting example embodiment of the disclosure, both the first gas distribution plate 304 and the second gas distribution plate 310 may have a thickness of less than approximately 25 millimeters, or less than approximately 15 millimeters, or even less than approximately 12.5 millimeters. In addition, both the first gas distribution plate 304 and the second gas distribution plate 310 may comprise a circular disc configuration having a radius of less than approximately 100 millimeters, or less than approximately 200 millimeters, or even less than approximately 300 millimeters.

In some embodiments of the disclosure, the second gas distribution plate 310 may be disposed over the top surface 306 of the first gas distribution plate 304, as shown in FIG. 3. The first gas distribution plate 304 and the second gas distribution plate 310 may be substantially the same and may therefore be aligned and coupled together (along with additional elements to be discussed) to form the gas distribution assembly 302.

In some embodiments of the disclosure, the gas distribution assembly 302 of FIG. 3 may further comprise one or more heating structures 316, wherein the one or more heating structures 316 are disposed between the first gas distribution plate 304 and the second gas distribution plate 310. In more detail, the one or more heating structures 316 may be disposed directly between the top surface 306 of the first gas distribution plate 304 and the bottom surface 314 of the second gas distribution assembly 310. The bottom surface of one or more heating structures may be disposed directly over and contacting the top surface 306 of the first gas distribution plate 304 and the top surface of the one or more heating structures 316 may be disposed directly under and contacting the bottom surface 314 of the second gas distribution plate 310.

In some embodiments of the disclosure, the one or more heating structures 316 comprise one or more 3D printed heating structures, i.e., the one or more heating structures may be formed by an additive manufacturing process in a layer-by-layer manner. In more detail, the one or more 3D printed heating structures may comprise a first dielectric layer 318, a second dielectric layer 320 and a resistive material 322 disposed and encapsulated between the first dielectric layer 318 and the second dielectric layer 320.

In some embodiments of the disclosure the first dielectric layer 318 may be 3D printed directly on the top surface 306 of the first gas distribution plate 304 such that the first dielectric layer 318 is disposed directly over the top surface 306 of the first gas distribution plate 304. The first dielectric material may comprise at least one of an alumina, a plastic, and a fluoropolymer (e.g., polytetrafluoroethylene). The first dielectric material may be 3D printed to a thickness of greater than 0.25 millimeters, or greater than 0.50 millimeters, or even greater than 1.00 millimeter. In addition the first dielectric layer 318 may have a cross sectional width w of less than 1 millimeter, or less than 3 millimeters or even less than 5 millimeters.

In some embodiments of the disclosure the resistive material 322, e.g., the heating element material, may be 3D printed on the top surface of the first dielectric layer 318 such that the resistive material 322 is disposed directly over the first dielectric layer 318. The resistive material may comprise at least one of aluminum, nichrome, nickel, chrome, and tungsten. The resistive material 332 may be 3D printed to a thickness of greater than 0.25 millimeters, or greater than 0.50 millimeters, or even greater than 1 millimeter. In addition the resistive material 322 may have a cross sectional line width less than the first dielectric layer and may further have a cross sectional line width of less than 1 millimeter, or less than 2 millimeters, or even less than 3 millimeters.

In some embodiments of the disclosure the second dielectric layer 320 may be 3D printed directly over and encapsulating the resistive material 322 such that the second dielectric layer is disposed directly over the top surface of the resistive material 322. The second dielectric material 320 may comprise at least one of an alumina, a plastic and a fluoropolymer (e.g., polytetrafluoroethylene). The second dielectric material 320 may be 3D printed to a thickness of greater than 0.25 millimeters, or greater than 0.50 millimeters, or even greater than 1.00 millimeter. In addition the second dielectric layer 320 may have a cross sectional line width w of less than 1 millimeter, or less than 3 millimeters, or even less than 5 millimeters.

Therefore, the 3D printing process forms one or more heating structures 316 comprising a resistive material encapsulated between a first dielectric layer and a second dielectric layer, the first and second dielectric layers providing electrical isolation for the resistive material. For example in some embodiments, the one or more 3D printed heating structures comprise at least one 3D printed trace establishing an electrically conductive path.

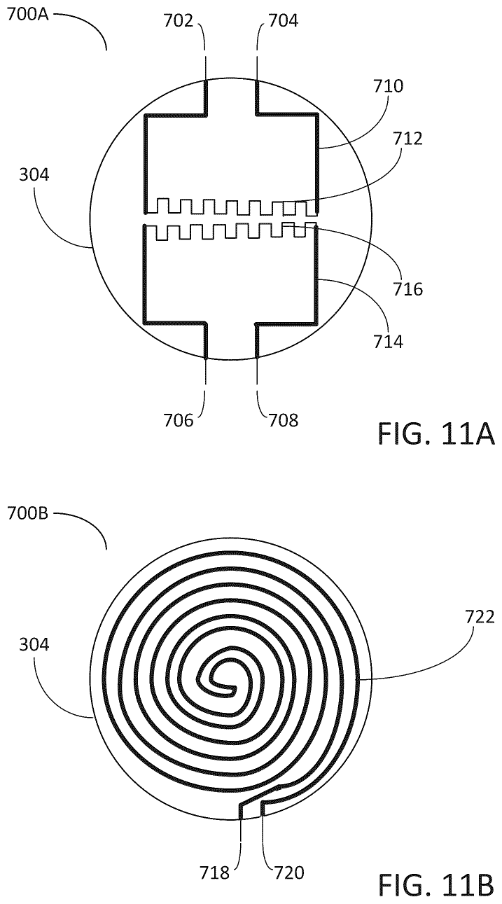

FIGS. 11A and 11B illustrate non-limiting example heating arrangements that may be utilized for electrical traces of various configurations and geometries depending on the thermal uniformity desired on the gas distribution assembly For example, FIG. 11A illustrates heating configuration 700A, which comprises the first gas distribution plate 304 and two independently controlled and 3D printed traces establishing electrically conductive paths. The first independently controlled heater comprises supply lead 702 and return lead 704 as well as resistive heating elements 710 and 712 (please note only the resistive heating element is shown for simplicity and it should be appreciated that the resistive heating element(s) shown may be encapsulated by dielectric materials). In this non-limiting example embodiment, the thicknesses of the electrically conductive paths are different for resistive heating elements 710 and 712 and are therefore able to provide a different power density to the completed showerhead assembly (to be discussed further herein). In addition, the heating configuration 700A comprises a second independently controlled heater comprising supply lead 706 and return lead 708, as well as resistive heating elements 714 and 716, as described above. As a further non-limiting example embodiment, FIG. 11B illustrates heating configuration 700B which comprises the first gas distribution plate 304 and a single independently controlled heater comprising supply lead 718 and return lead 720 as well as the spiral configuration heating element 722.

In some embodiments of the disclosure, the one or more heating structures making up the one or more independently controlled heaters may provide a power density of at least 100 watts per square inch, or a power density of at least 200 watts per square inch, or even a power density of at least 400 watts per square inch.

In some embodiments, the cross sectional width and thickness of the resistive material 322 (see FIG. 3) may be variable within the one or more 3D printed heated structures to enable variable power density within the showerhead. In more detail, the cross sectional width and thickness of the 3D printed resistive material may be varied across the surface of the first gas distribution plate to enable different power density zones across the gas distribution assembly. For example, the showerhead assembly of the current disclosure may comprise separate and isolated apertures for two or more precursors, such that the precursors do not mix in the showerhead but rather upon direct interaction with the heated substrate below the showerhead. Premature mixing of the precursors may result in unwanted gas-phase interactions and the formation of unwanted reaction by-products. Therefore, in some embodiments the cross sectional width and/or thickness of the resistive material 322 is selected for a first group of a plurality of apertures supplying a first gas-phase reactant and a second, different, cross sectional line width and/or thickness of the resistive material 322 is selected for a second group of a plurality of apertures supplying a second different gas-phase reactants. Therefore, the power density and the resulting temperature of the gas distribution assembly can be varied locally to accommodate different gas-phase chemistries.

In some embodiments of the disclosure, the power density of the one or more heating structures may be varied across the gas distribution assembly such that a desired thermal profile can be created. For example, in some embodiments, the showerhead assembly may be deposed in a deposition system and said deposition system may include one or more locations which are at a lower average temperature than the remainder of the deposition system, e.g., resulting from an exhaust region or a load-transfer region. The one or more locations which are below the average temperature may result in cooler regions on the showerhead assembly and particular on the gas distribution assembly. To counteract this localized cooling effect, the power density of the one or more heating structures proximate to the cooler zone(s) may be increased to off-set the reduced temperature and attain a desired temperature uniformity across the gas distribution assembly. Therefore, in some embodiments, the power density of the one or more heating structures may be varied by adjusting the density of the resistive heating material across the surface of the first gas distribution.

In some embodiments of the disclosure, the one or more heating structures may comprise one or more independently controlled heating zones. As a non-limiting example embodiment, the differential temperature across the gas distribution assembly may vary due to proximity to the heated substrate and due to a periphery cooling zone. To off-set the differential temperature across the gas distribution, two or more independently controlled heating zones may be printed onto the first gas distribution plate (or the second gas distribution plate) such that the temperature and particularly the temperature uniformity across the gas distribution assembly may be better controlled. The embodiments of the disclosure allow for multiple zones of independently controlled temperature zones, since the restrictions due to the footprint of the heater (e.g., for coil/cable heaters) is reduced for printed heating structures such that complex multi-zone temperature control can be achieved.

Referring back to FIG. 3, the gas distribution assembly 302 may further comprise a brazing material 324 disposed between the first gas distribution plate 304 and the second gas distribution plate 310. In further embodiments, the brazing material 324 may further be disposed between and in contact with the one or more heating structures 316.

In more detail, the first gas distribution plate 304, second gas distribution plate 310, and the one or more heating structures 316 are required to be hermetically sealed to one another such that when subsequent processes form a plurality of apertures through the gas distribution assembly, there is substantially no leakage of precursor gases between the elements of the gas distribution assembly. In some embodiments, the brazing material 324 may be applied to at least one of the bottom surface 314 of the second gas distribution plate 310 or to the top surface 306 of the first gas distribution plate 304. When applying the brazing the material to the top surface 306 of the first distribution plate 304, the brazing material 324 is preferably applied and disposed between the one or more heating structures 316. In some embodiments, the thickness of the brazing material applied may have a thickness substantial equal to the thickness of the one or more heating structures. In some embodiments of the disclosure, the brazing materials may comprise aluminum or an aluminum alloy.

In some embodiment of the disclosure, the gas distribution assembly 302 may further comprise a plurality of apertures 326 extending from the top surface 312 of the second distribution plate 310 to the bottom surface 308 of the first gas distribution plate 304. For, example the plurality of apertures 326 may be utilized to transport reactant gas(es) from chamber 106 to the substrate 112 (see FIG. 1). The plurality of apertures 326 are generally cylindrical in shape, although alternative geometries may be utilized, for more detailed information regarding the plurality of apertures may be found in US. Pat. App. Pub. No. US 2016/0024656, filed on Jul. 28, 2014, titled SHOWERHEAD ASSEMBLY AND COMPONENTS THEREOF, all of which is hereby incorporated by reference and made a part of this specification.

In some embodiments of the disclosure, the plurality of apertures 326 extending from the top surface 312 of the second distribution plate 310 to the bottom surface 308 of the first distribution plate 304 may further extend through the brazing material 324. In more detail, the embodiments of the invention allow for a showerhead assembly with a plurality of apertures (e.g., hundreds, even thousands of apertures) wherein the embedded one or more heating structures are disposed between the apertures such that the formation of the plurality of apertures does not damage or even destroy an individual heating structure. The precision required to enable the one or more heating structures to be disposed between the plurality of apertures is enabled by the printing methods described herein.

Alternative embodiments of the disclosure are illustrated in FIG. 4 which shows an expanded view of a portion of exemplary gas distribution assembly 402, wherein gas distribution assembly 402 shares some similar features with gas distribution assembly 302 and therefore only the relevant differences between gas distribution assembly 402 and gas distribution assembly 302 are discussed herein.

Gas distribution assembly 402 includes a first gas distribution plate 404 and a second gas distribution plate 410 disposed over the first gas distribution plate 404. In contrast with gas distribution assembly 302, the gas distribution assembly 402 comprises a first gas distribution plate 404 further comprising one or more channels 428 disposed in a top surface 406 of the first gas distribution plate 404. The one or more channels 428 may be sized and configured such that in some embodiments, the one or more heating structures 416 may be disposed within the one or more channels 428. For example, the one or more channels may have a cross sectional width of less than 1 millimeter, or less than 3 millimeters or even less than 5 millimeters. In addition, the one more channels have a depth of less than 0.1 millimeters, or less than 0.5 millimeters, or even less than 1 millimeter.

In order to couple the first gas distribution plate 404 to the second gas distribution plate 410, a brazing material 424 may be utilized. Therefore, in some embodiments of the disclosure, the gas distribution assembly 402 may also comprise a blanket brazing material 424 disposed over the top surface 406 of the first gas distribution plate 404 and covering the one or more heating structures 416 with brazing material 424. In some embodiments, a plurality of apertures 426 extend from the top surface 412 of the second gas distribution plate 410 to the bottom surface 408 of the first gas distribution plate 404 such that the plurality of apertures 426 are disposed between the one or more channels 428 with the one or more heating structures 416 disposed therein.

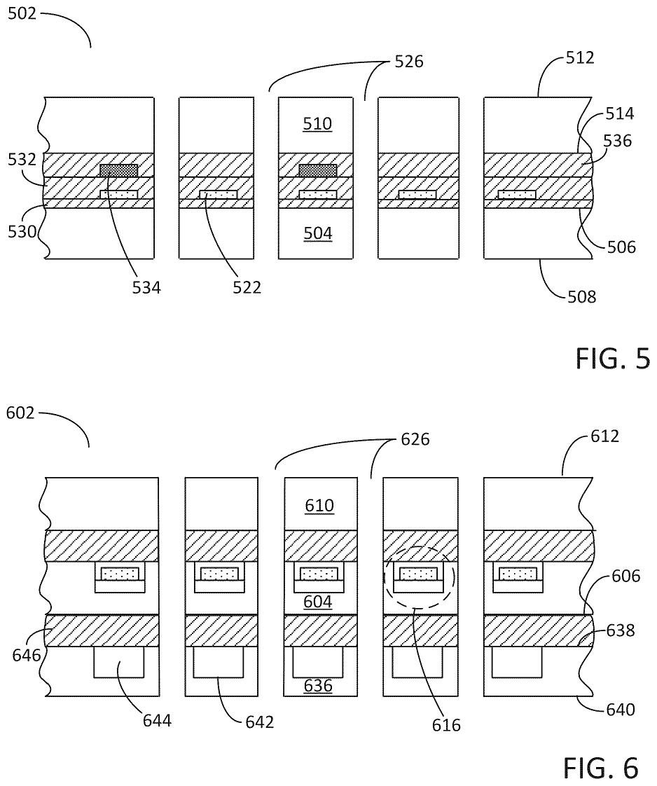

Further embodiments of the disclosure are illustrated in FIG. 5 which shows an expanded view of a portion of exemplary gas distribution assembly 502, wherein gas distribution assembly 502 shares some similar features with gas distribution assembly 302. Therefore, only the relevant differences between gas distribution assembly 302 and gas distribution assembly 502 are discussed herein.

Gas distribution assembly 502 may comprise a first gas distribution plate 504 and a second gas distribution plate 510 with one or more heating structures provided there between, as with the previously described embodiments. However, gas distribution assembly 502 may further comprise one or more heating structures disposed on a dielectric substrate. The heating structures may further comprise a polyimide layer, and in addition one or more sensors, such as one or more thermocouples, may also be disposed between the first gas distribution plate 504 and the second gas distribution plate 510.

In more detail, the one or more heating structures disposed within gas distribution assembly 502 may comprise a first polyimide layer 530, such as a polyimide substrate, which may be disposed on the top surface 506 of the first gas distribution plate 504. In some embodiments of the disclosure, the first polyimide layer 530 may have a thickness of less than 0.250 millimeters, or less than 0.125 millimeters, or even less than 0.100 millimeters. Disposed directly on and/or in the first polyimide layer 530 may be one or more heating structures. In some embodiments the one or more heating structures may comprise one or more printed heating structures, for example, the one or more printed heating structures may be provided over the polyimide layer 530 utilizing a screen printing techniques, wherein a resistive material 522 may comprise a conductive ink, such as conductive silver or carbon. The resistive material 522 may be printed to a thickness of less than 0.20 millimeters, or less than 0.50 millimeters, or even less than 1.00 millimeter. In addition, the resistive material 500 may have a cross sectional line width less than 1 millimeter, or less than 2 millimeters, or even less than 3 millimeters. As in previous embodiments, the cross sectional line width and/or thickness of the resistive material 522 may be varied to enable variable power density heating of the gas distribution assembly 502.

Disposed over the resistive material 522 and, in some embodiments, disposed directly over the resistive material 522 is an additional dielectric layer 532. In some embodiments of the disclosure, the additional dielectric layer is disposed over dielectric layer 530 and the resistive material 522 such that the resistive material 522 is encapsulated by dielectric material. In some embodiments of the disclosure, the additional dielectric material 532 may comprise a silicon oxide or a silicon nitride, whereas in other embodiments of the disclosure the additional dielectric material 532 may comprise an additional polyimide layer.

In some embodiments of the disclosure, one or more temperature sensors, such as, one or more thermocouples may be disposed over the resistive material 522 and particularly directly over additional dielectric material 532. In some embodiments, the one or more thermocouples 534 are disposed over the additional dielectric material 532 to enable the measurement of temperature across the gas distribution assembly in one or more zones, such that, independent temperature monitoring and control can be maintained across the gas distribution assembly 502. Disposed over the one or more sensors 534 (e.g., one or more thermocouples) is a further additional dielectric material 536, which provides electrical isolation and independence of each of the one or more sensors 534. For example, the further additional dielectric material 536 may comprise a silicon oxide or a silicon nitride, whereas in some embodiments of the disclosure the further additional dielectric material may comprise a polyimide layer disposed directly over the one or more sensors 534 and directly below the bottom surface 514 of the second gas distribution assembly 510.

The gas distribution assembly 502 may also comprise a plurality of apertures 526 which extend from the top surface 512 of the second gas distribution plate 510 through to the bottom surface 508 of the first gas distribution plate 504. In some embodiments of the disclosure the plurality of apertures 526 may be disposed between both the resistive material 522 (e.g., the heating element) and the one or more sensors 534.

In additional embodiments of the disclosure, a showerhead assembly may be provided that includes both means for heating the gas distribution assembly as well for cooling the gas distribution assembly, thereby providing greater control over the temperature uniformity of the showerhead assembly and particular over the surface of the gas distribution assembly facing the substrate.

Therefore, embodiments of the disclosure are illustrated in FIG. 6 which shows an expanded cross section view of a portion of exemplary gas distribution assembly 602, wherein gas distribution assembly 602 shares some similar features with gas distribution assembly 402 and therefore only the relevant differences between gas distribution assembly 402 and gas distribution assembly 602 are discussed herein.

The gas distribution assembly 602 comprises a first gas distribution plate 604 and a second gas distribution 610 disposed over and coupled to the first gas distribution 604. In contrast to the previously described exemplary gas distribution assemblies, gas distribution assembly 602 further comprises a third gas distribution plate 636. Comprising a top surface 638 and a bottom surface 640, the third gas distribution plate 636 may be attached to either the first gas distribution plate 604 (as shown in FIG. 6) or the second gas distribution plate 610. As shown in FIG. 6, the third gas distribution panel 636 may be attached to the bottom surface 606 of the first gas distribution panel 604 although the third gas distribution plate 636 may alternatively or, in addition to, may be attached to the top surface 612 of the second gas distribution plate 610 (not shown). However, in some embodiments of the disclosure, it may be advantageous to position the third gas distribution plate 636 proximate to the exposed surface of the gas distribution assembly most proximate to the heated substrate, such that the cooling means for the gas distribution assembly may be proximate to the high temperature substrate.

In some embodiments of the disclosure, the third gas distribution plate 636 further comprises one or more trenches 642 extending from the top surface 638 of the third gas distribution plate 636 into a portion of a body of the third gas distribution plate 636. For example, the one or more trenches 642 may have a cross sectional width of less than 5 millimeters, or less than 3 millimeters or even less than 1 millimeter. In addition, the one more trenches 642 may have a depth from the top surface 638 into a portion of the body of less than 5 millimeters, or less than 3 millimeters, or even less than 1 millimeter. In some embodiments the one or more trenches 642 may be attached to either the first gas distribution plate 604 or the second gas distribution plate 610, thereby forming one or more sealed channels 644 configured for distributing a cooling fluid throughout the gas distribution assembly.

In some embodiments of the disclosure, the one or more sealed channels may further comprise two or more independent sealed channels configured for counterflow cooling of the showerhead assembly and particularly for cooling the gas distribution assembly 602.

In some embodiments of the disclosure, the third gas distribution plate 602 may be coupled to the first and/or second gas distribution plate utilizing an additional brazing material 646. For example, in some embodiments of the disclosure, the additional brazing material may comprise at least one of aluminum or an aluminum alloy. As illustrated in FIG. 6, the additional brazing material 646 may be disposed between the first gas distribution plate 604 and the third gas distribution plate 636, whereas in some embodiments, the additional brazing material 646 may be disposed between the second gas distribution plate 610 and the third gas distribution plate 636. In some embodiments of the disclosure, the additional brazing material may be applied to bottom surface 606 of the first gas distribution plate 604. In some embodiments of the disclosure, the brazing material may be provided in the form of a brazing paste or a brazing foil.

In some embodiments of the disclosure, a plurality of apertures 626 may further extend from the top surface 612 of the second gas distribution plate 610 to the bottom surface 640 of the third gas distribution 636. In further embodiments, the plurality of apertures 626 may be disposed not only between the one or more heating structures 616, but also disposed between the one or more sealed cooling channels 644 such that a hermetically sealed gas distribution assembly may be provided that includes both heating means and cooling means for improved thermal uniformity control of the gas distribution assembly.

In addition to the showerhead assemblies and particularly gas distribution assemblies provided herein, the embodiments of the disclosure may also provide methods for controlling the temperature uniformity of a showerhead assembly utilized for distributing a gas within a reaction chamber and particular for controlling the temperature uniformity across the surface of the gas distribution assembly wherein the exposed surface of the gas distribution assembly may be adjacent to the substrate.

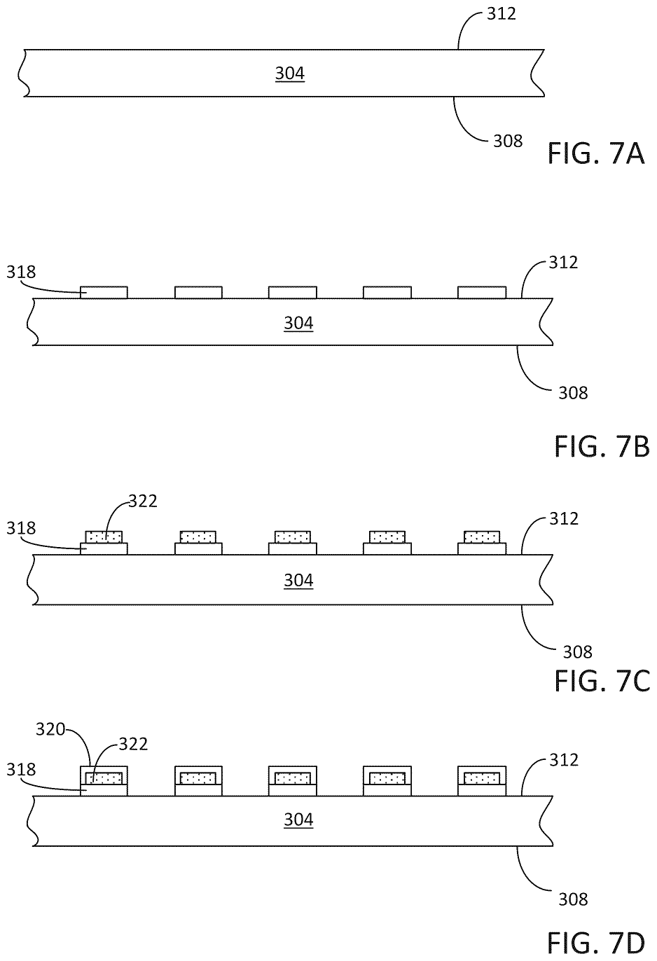

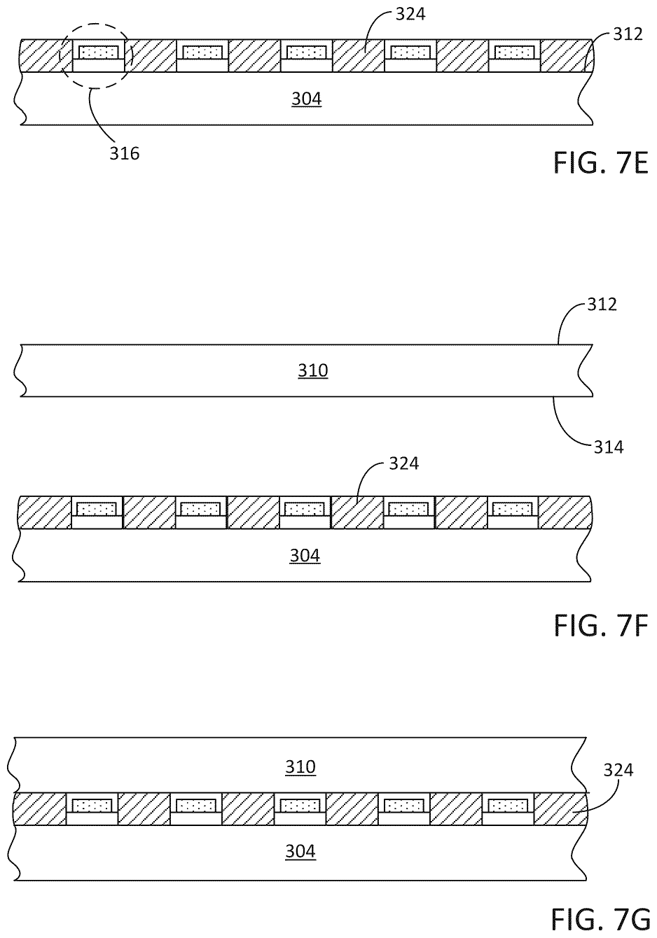

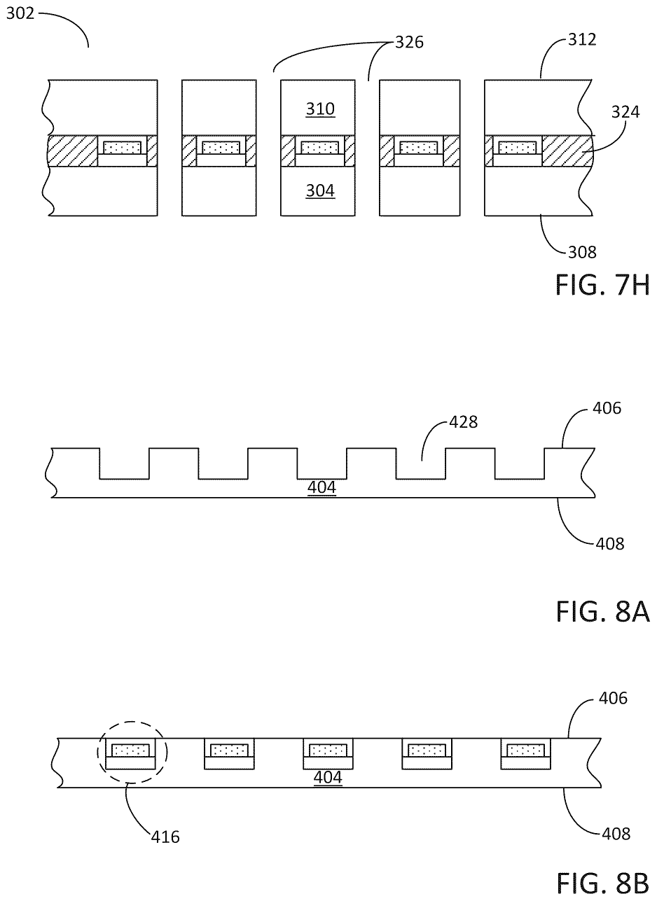

In more detail, a non-limiting example of the methods of the disclosure may be illustrated with accompanying FIGS. 7A-7H, which illustrates an exemplary method of fabricating the gas distribution assembly 302 of FIG. 3. Methods of the current disclosure may comprise, providing a first gas distribution plate 304 comprising a top surface 312 and a bottom surface. 308. For example, the first gas distribution plate 304 may be fabricated from one or more of aluminum, titanium, nickel, nickel alloys, ceramics, stainless steel and Hastelloy. In addition, methods may comprise selecting the first gas distribution plate to have a thickness of less than approximately 25 millimeters, or less than approximately 15 millimeters, or even less than approximately 12.5 millimeters. In addition, the first gas distribution plate 304 may comprise a circular disc configuration having a radius of less than approximately 100 millimeters, or less than approximately 200 millimeters, or even less than approximately 300 millimeters.

Having provided the first gas distribution plate 304, the method may continue by printing one or more heating structures on the top surface 312 of the first gas distribution plate 304 (alternative the one or more heating structures may be printed on a bottom surface of a second gas distribution). In more detail, FIG. 7B illustrates the formation of an initial portion of the one or more heating structures, the initial portion comprising a first dielectric layer 318. In some embodiments the first dielectric layer may be disposed directly on the upper surface 312 of first gas distribution plate 304 (as shown in FIG. 7B), whereas in other embodiments (not shown) the first dielectric layer may be disposed directly on the bottom surface of a second gas distribution plate 310. The first dielectric layer 318 may comprise one or more of an alumina, a plastic, and a fluoropolymer (e.g., polytetrafluoroethylene). The first dielectric layer may be 3D printed to a thickness of greater than 0.25 millimeters, or greater than 0.5 millimeters, or even greater than 1.0 millimeter. In addition the first dielectric layer 318 may have a cross sectional width of less than 1 millimeter, or less than 3 millimeters or even less than 5 millimeters.

Referring to FIG. 7C, having provided the first dielectric layer 318 over the top surface 312 of the first gas distribution plate 304, methods may further comprise, printing a resistive material 322 over the first dielectric layer 318 and may further comprise, 3D printing the resistive material 322 directly over the first dielectric layer 318. The resistive material may comprise one or more of aluminum, nickel, chrome, and tungsten. The resistive material may be 3D printed to a thickness of greater than 0.25 millimeters, or greater than 0.50 millimeters, or even greater than 1.00 millimeter. In addition, the resistive material may have a cross sectional width of less than 1 millimeter, or less than 2 millimeters, or even less than 3 millimeters. In some embodiments, the thickness and/or width of the resistive material 322 may be variable to enable variable power density heating to the gas distribution assembly.

Referring to FIG. 7D, having provided the resistive material 322 over the first dielectric layer 318 a second dielectric layer 320 may be printed over the resistive material 322 such that the second dielectric layer 320 is directly over the resistive material 322 and the second dielectric layer 320 in conjunction with the first dielectric layer 318 encapsulates the resistive material 322. The second dielectric layer may comprise one or more of an alumina, a plastic, and a fluoropolymer (e.g., polytetrafluoroethylene). The second dielectric 320 layer may be 3D printed to a thickness of greater than 0.25 millimeters, or greater than 0.5 millimeters, or even greater than 1 millimeter. In addition the second dielectric layer 320 may have a cross sectional width of less than 1 millimeter, or less than 3 millimeters, or even less than 5 millimeters.

Having 3D printed one or more heating structures, either on the first gas distribution plate 304 or on a second gas distribution plate, the methods of disclosure may continue by the coupling the first gas distribution plate to the second gas distribution plate such that the one or more heating structures are dispose between the top surface of the first gas distribution plate and the bottom surface of the second gas distribution plate. In embodiments of the disclosure, the coupling of the first gas distribution plate to the second gas distribution plate may be achieved utilizing a brazing material. For example, coupling the first gas distribution plate to the second gas distribution plate comprises providing a brazing material over at least one of the top surface of the first distribution plate or the bottom surface of the second gas distribution plate. As illustrated in FIG. 7E, methods may comprise providing a brazing material 324 of the top surface 312 of the first distribution plate 304, the brazing material 324 being disposed between the one or more heating structures 316. The coupling of the first gas distribution plate 304 to the second gas distribution plate may further comprise providing the second gas distribution plate 310 comprising a top surface 312 and a bottom surface 314 (see FIG. 7F) and heating the first gas distribution plate 304, the second gas distribution plate 310, and the brazing material 324 so as to braze the first gas distribution plate 304 and the second gas distribution plate 310 to one another (see FIG. 7G).

Once the first gas distribution plate 304 and second gas distribution plate 310 are coupled together with the brazing material 324, the methods of the disclosure may comprise forming a plurality of apertures 326, which may extend from the top surface 312 of the second gas distribution plate 310 to the bottom surface 308 of the first gas distribution plate 304, as illustrated in FIG. 7H. For example, the plurality of apertures 326 may be formed by a drilling process and forming the plurality of apertures 326 may comprise extending the plurality of apertures through the brazing material 324.

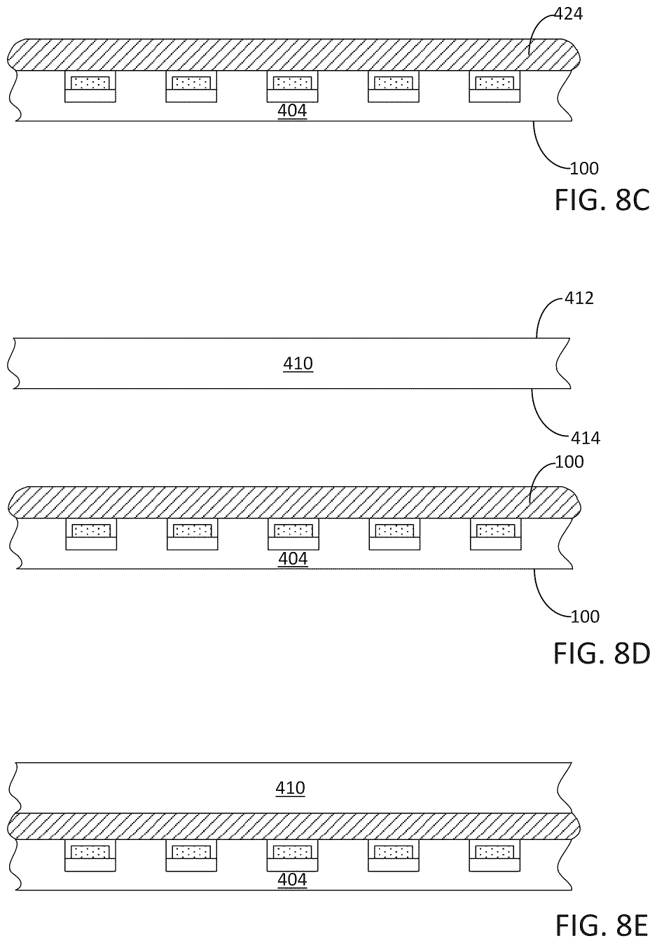

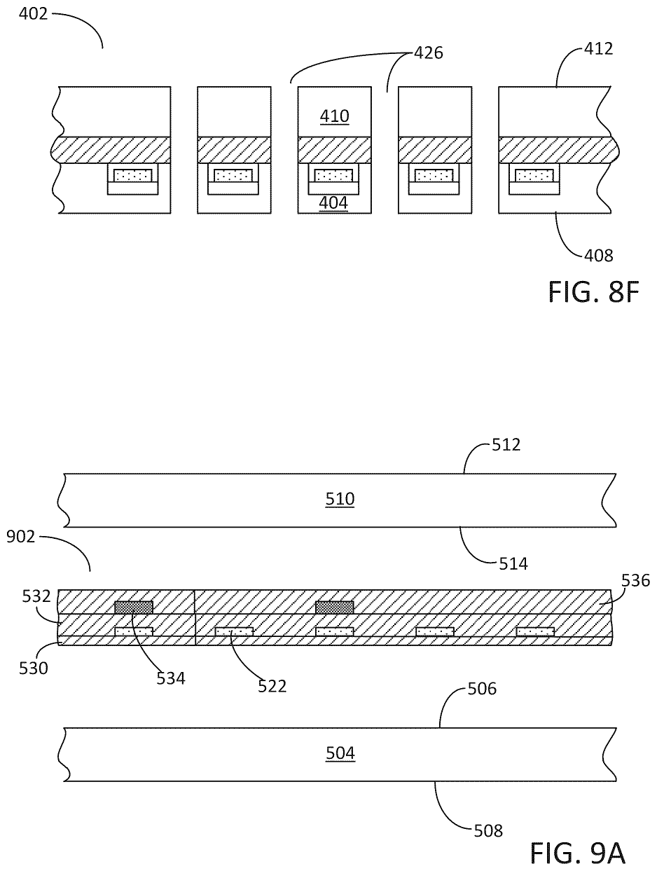

In alternative embodiments of the disclosure, a non-limiting example of the methods of the disclosure may be illustrated with accompanying FIGS. 8A-8F, which illustrates the method of making the exemplary gas distribution assembly 402 of FIG. 4. Methods of the current disclosure may comprise, providing a first gas distribution plate 404 comprising a top surface 406 and a bottom surface 408. In some embodiments of the disclosure, the method may further comprise, forming one or more channels 428 in the top surface of the first gas distribution and printing one or more heating structures 416 such that the one or more heating structures 416 are disposed in the one or more channels 428, (as illustrated in FIGS. 8A and 8B). Once the one or more heating structures are disposed in the one or more channels, a brazing material 424 may be provided over either the first gas distribution plate 404 (as shown in FIG. 8C) or over the second gas distribution plate. A second gas distribution plate 410 may be provided, comprising a top surface 412 and a bottom surface 414 surface, and the first and the second gas distribution plate may be brazed together (as shown in FIG. 8D). Once brazed together (FIG. 8E), the gas distribution assembly may undergo an aperture formation process, such as a drilling process, thereby forming a plurality of apertures 426 extending from the top surface 412 of the second gas distribution plate 410 to the bottom surface 408 of the first gas distribution plate 404 (see FIG. 8F).

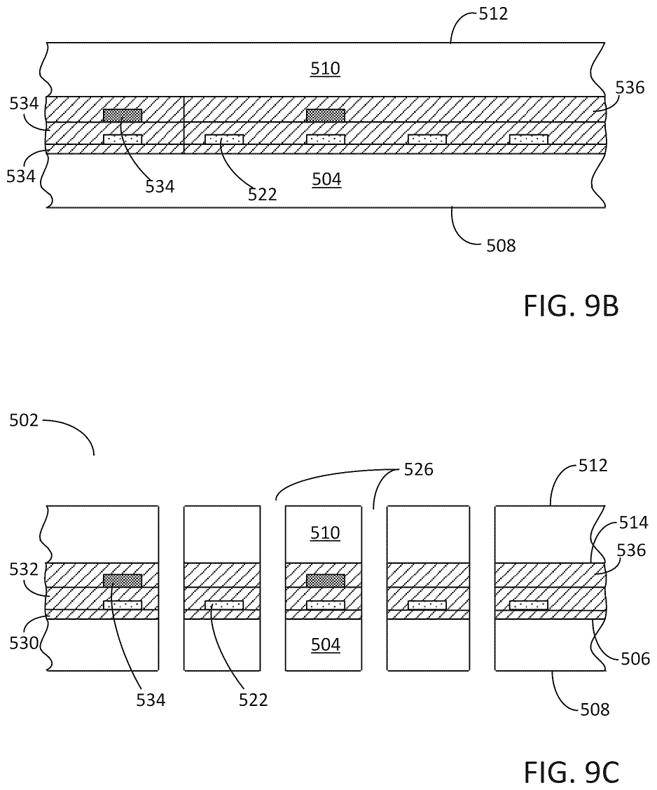

In alternative embodiments of the disclosure, a non-limiting example of the methods of the disclosure may be illustrated with accompanying FIGS. 9A-9C, which illustrates the method of making the exemplary gas distribution assembly 502 of FIG. 5. Methods of the current disclosure may comprise providing a first gas distribution plate 504 comprising a top surface 506 and a bottom surface 508. In addition, methods may also comprise providing a second gas distribution plate 510 comprising a top surface 512 and a bottom surface 514.

The methods may also comprise providing a multilayered structure 902, the multilayered structure 902 comprising a first polyimide layer 530, such as a polyimide substrate. The multilayered structure 902 may further comprise one or more heating structures 522 disposed on the first polyimide layer 530, the one or more heating structure 522 comprising one or more printed heating structures. For example, the one or more printed heating structures may comprise a screen printed resistive material, such as, for example, comprising silver or copper. The multilayered structure 902 may further comprise an additional dielectric material 532 disposed directly over the one or more heating structures, the additional dielectric material 532 may comprise a silicon oxide or a silicon nitride, or alternatively the additional dielectric material 532 may comprise an additional layer of polyimide. The multilayered structure 902 may further comprise one or more temperature sensors 534, such as, one or more thermocouples, which may be disposed directly over the additional dielectric material 532. Finally, the multilayered structure may comprise a further dielectric material 536, which may comprise a silicon oxide, a silicon nitride, or a further additional polyimide layer disposed directly over the one or more sensors 534.

The methods of the disclosure may continue by coupling the first gas distribution plate 510, the multilayered structure 902, and the second gas distribution plate 504 to one another to form a hermetically sealed partially formed gas distribution assembly. The coupling process may comprise a bonding process wherein the first gas distribution plate 510, the multilayered structure 902, and the second gas distribution plate 504 are placed in a bonding apparatus to perform a bonding process. In some embodiments of the disclosure, the bonding process may comprise applying a pressure between the first gas distribution plate 510 and second gas distribution plate 510 with the multilayer structure 902 being disposed between the two gas distribution plates. In addition to applying pressure to the first gas distribution plate 504 and the second gas distribution plate 510, the bonding process may also comprise heating the first gas distribution plate 504 and the second gas distribution plate 510. For example, the assembly comprising the first gas distribution plate 504, the multilayered structure 902, and the second gas distribution plate 510 may be situated in a bonding apparatus and pressure may be applied to the assembly while heating the assembly to a temperature of approximately greater than 250° C. The bonding process results in the partially formed gas distribution assembly as illustrated in FIG. 9B.

Once the assembly has been bonded together, the methods may continue by forming a plurality of apertures from the top surface 512 of the second gas distribution plate 510 through to the bottom surface 508 of the first gas distribution plate 504, the plurality of apertures being disposed between the one or more heating structures and the one or more sensors, as illustrated by gas distribution assembly 502 of FIG. 9C.

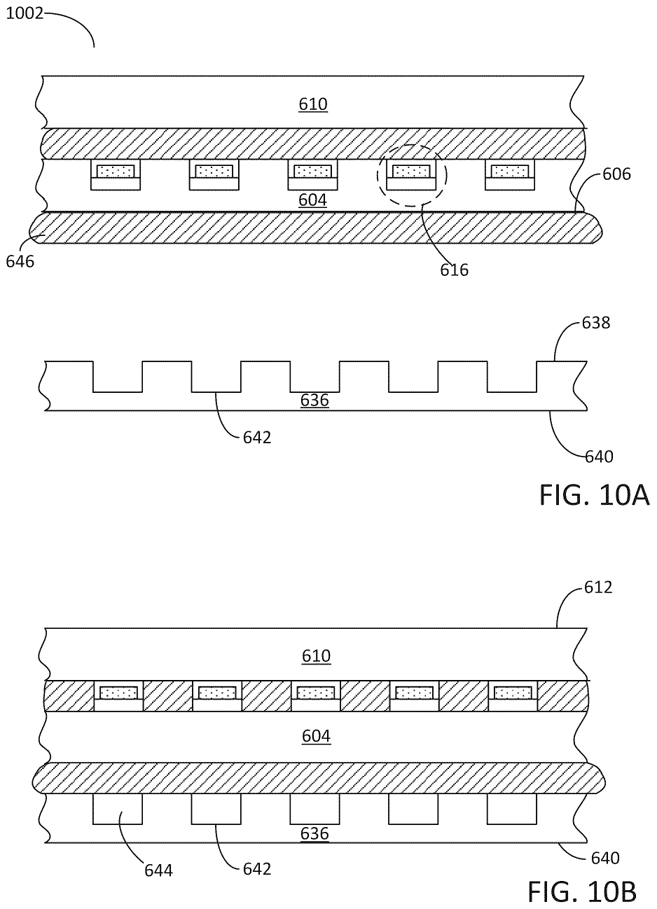

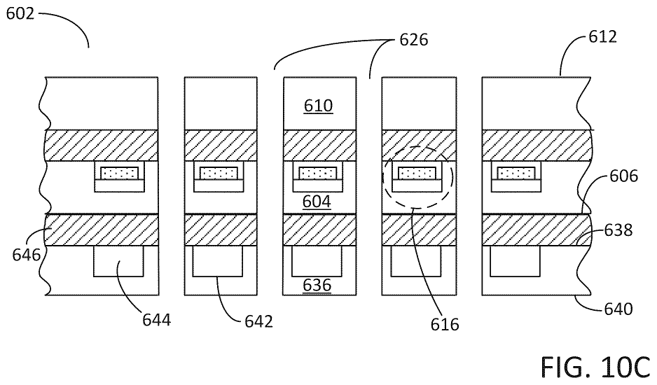

In alternative embodiments of the disclosure, a non-limiting example of the methods of the disclosure may be illustrated with accompanying FIGS. 10A-10C, which illustrates the method of making the exemplary gas distribution assembly 602 of FIG. 6. Methods of the current disclosure may comprise providing a partially fabricated gas distribution assembly 1002 comprising a first gas distribution plate 604, a second gas distribution plate 610, and one or more heating structures 616 disposed there between, the methods of forming such a partially fabricated gas distribution assembly 1002 is described herein with reference to FIGS. 8A-8E and therefore is not repeated herein. The methods of the disclosure may also comprise providing an additional brazing material 646 on the bottom surface 606 of the first gas distribution plate. The methods of the disclosure may also comprise providing a third gas distribution plate 636 wherein the third gas distribution plate 636 further comprises one or more trenches 642 extending from the top surface 638 of the third gas distribution plate 636 into a portion of a body of the third gas distribution plate 636. The one or more trenches 642 may be formed in the top surface 638 of the third gas distribution plate 636 by utilizing a machining process.

The methods of the disclosure may continue by coupling the partially fabricated gas distribution assembly 1002 to the third gas distribution plate 636. The coupling process may be achieved by contacting the additional brazing material 646 to the top surface 638 of the third gas distribution plate 636 and heating the assembly such that the additional brazing material couples the third gas distribution plate to the partially fabricated gas distribution assembly 1002, as illustrated in FIG. 10B. The coupling of the partially fabricated gas distribution assembly 1002 to the third gas distribution plate 636 results in the formation of one or more sealed channels 644, which can be utilized for flowing a cooling medium (e.g., a cooling fluid) through the gas distribution assembly.

Once the assembly has been coupled together, the methods may continue by forming a plurality of apertures from the top surface 612 of the second gas distribution plate 610 through to the bottom surface 640 of the third gas distribution plate 636, the plurality of apertures being disposed between the one or more heating structures and the one or more sealed channels, as illustrated by gas distribution assembly 602 of FIG. 10C.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for controlling the temperature uniformity of a showerhead assembly utilized for distributing a gas within a reaction chamber, the method comprising:
providing a first gas distribution plate comprising a first top surface and a first bottom surface;
providing a second gas distribution plate comprising a second top surface and a second bottom surface;
printing one or more heating structures over either the first top surface or the second bottom surface;
coupling the first gas distribution plate to the second gas distribution plate such that the one or more heating structures are disposed between the first top surface and the second bottom surface; and
forming a plurality of apertures extending from the second top surface to the first bottom surface.

2. The method of claim 1, wherein printing the one or more heating structures comprises 3D printing the one or more heating structures.

3. The method of claim 2, wherein 3D printing the one or more heating structures comprises:
3D printing a first dielectric layer over the first top surface;
3D printing a resistive material over the first dielectric layer; and
3D printing a second dielectric layer over the resistive material and encapsulating the resistive material.

4. The method of claim 2, wherein 3D printing the one or more heating structures further comprises 3D printing the resistive material with a variable line width to enable variable power density within the shower assembly.

5. The method of claim 1, wherein coupling the first gas distribution plate to the second gas distribution plate comprises providing a brazing material over at least one of the first top surface or the second bottom surface.

6. The method of claim 5, wherein providing a brazing material further comprises providing a brazing material over the first top surface, the brazing material being disposed between the one or more heating structures.

7. The method of claim 6, wherein coupling the first gas distribution plate to the second gas distribution plate, further comprises heating the first gas distribution plate, the second gas distribution plate, and the brazing material so as to braze the first gas distribution plate and the second gas distribution plate to one another.

8. The method of claim 5, wherein forming a plurality of apertures, further comprises forming a plurality of apertures extending through the brazing material.

9. The method of claim 1, further comprising:
forming one or more channels in the first top surface; and
printing the one or more heating structures such that the one or more heating structures are disposed in the one or more channels.

10. The method of claim 9, further comprising providing a blanket layer of brazing material over the first top surface and a top surface of the one or more heating structures.

11. The method of claim 1, further comprising:
providing a third gas distribution plate, the third gas distribution plate comprising a third top surface and a third bottom surface;
forming one or more trenches extending from the third top surface into a portion of a body of the third gas distribution plate; and
coupling the third top surface to either the first gas distribution plate or the second gas distribution plate.

12. The method of claim 11, wherein coupling the third top surface to either the first gas distribution plate or the second gas distribution plate further comprises forming one or more sealed channels configured for distributing a cooling fluid throughout the showerhead assembly.

13. The method of claim 12, wherein forming one or more sealed channels comprises forming two or more independent sealed channels configured for counterflow cooling of the showerhead assembly.

14. The method of claim 11, wherein forming a plurality of apertures further comprising forming a plurality of apertures extending from the third top surface to the third bottom surface.

15. The method of claim 14, wherein forming a plurality of apertures extending from the third top surface to the third bottom surface further comprises forming the plurality of apertures such that the plurality of apertures are disposed between the one or more sealed channels.

16. The method of claim 1, wherein printing one or more heating structures further comprises printing one or more independently controlled heating zones.

17. The method of claim 1, wherein printing the one or more heating structures further comprises:
printing the one or more heating structures directly over a polyimide substrate; and
bonding the polyimide substrate to the first top surface.

18. The method of claim 17, further comprising printing one or more thermocouples directly over the polyimide substrate.

19. The method of claim 18, further comprising forming a dielectric material over the one or more printed heating elements and the one or more printed thermocouples.

20. The method of claim 19, wherein coupling the first gas distribution plate to the second gas distribution plate further comprises hermetically bonding the first gas distribution plate to the second gas distribution plate, wherein bonding comprise:
applying a pressure between the first gas distribution plate and the second gas distribution plate; and
heating the first gas distribution plate and the second gas distribution plate.

21. The method of claim 19, wherein forming a plurality of apertures extending from the second top surface to the first bottom surface further comprises forming a plurality of apertures extending through both the dielectric material and the polyimide substrate, wherein the plurality of apertures are disposed between the one or more heating structures and the one or more thermocouples.

22. The method of claim 1, wherein printing the one or more heating structures further comprises printing one or more heating structures configured to provide a power density of at least 200 watts per square inch.
